(19) United States
(12) Patent Application Publication
(10) Pub. No.: US 2026/0324351 A1
(43) Pub. Date: Oct. 15, 2026

(54) INTER-FLOOR TRANSPORT DEVICE AND INTER-FLOOR TRANSPORT SYSTEM INCLUDING THE SAME

(71) Applicant: Murata Machinery, Ltd., Kyoto-shi, Kyoto (JP)

(72) Inventor: Yasuhisa ITO, Kyoto (JP)

(21) Appl. No.: 19/484,994

(22) PCT Filed: Feb. 2, 2024
(86) PCT No.: PCT/JP2024/003432

§ 371 Date: Nov. 17, 2025

(30) Foreign Application Priority Data
Jun. 21, 2023 (JP) 2023-101463

(51) Int. Cl. H10P 72/30; B66B 9/00; B66B 11/06

(52) U.S. Cl. CPC H10P 72/3222; B66B 9/00; B66B 11/06; H10P 72/3214; H10P 72/3218; H10P 72/3221

(57) ABSTRACT

An inter-floor transport device that transports an article between a plurality of floors separated in an up-down direction includes a lifting base to support the article to be transported, a plurality of suspenders to suspend the lifting base from above, and a lifting device that is installed above the lifting base to raise the lifting base to a floor on an upper side from a floor on a lower side or lower the lifting base to the floor on the lower side from the floor on the upper side through an opening in a floor surface of a floor by winding up or unwinding the suspenders.

### BACKGROUND OF THE INVENTION

### 1. Field of the Invention

The present invention relates to inter-floor transport devices and particularly relates to inter-floor transport devices to transport an article between a plurality of floors separated in an up-down direction, and an inter-floor transport system including the same.

### 2. Description of the Related Art

Japanese Patent No. 3593289 describes article transport equipment. This article transport equipment includes a guide rail extending in a vertical direction across a plurality of floors, a lifting body that moves in an up-down direction along this guide rail, and a transfer device that transfers a container transported by the lifting body onto a support body of a selective holder. Accordingly, the container is transferred onto the lifting body from the support body of the selective holder provided on a certain floor, and then the lifting body is moved to a different floor. Furthermore, on the floor of a destination, the container supported on the lifting body is transferred onto a support body of a selective holder provided on that floor. As a result, the container, which is an article, can be transported to the different floor.

### SUMMARY OF THE INVENTION

However, the article transport equipment described in Japanese Patent No. 3593289 includes the guide rail extending in the vertical direction across the plurality of floors, and along this, the lifting body transports the container in the up-down direction. Therefore, even when the article to be transported is small, the equipment for transporting the article across the plurality of floors becomes large, and the floor area required for installing the article transport equipment becomes large. In addition, since the rail in the vertical direction for causing the lifting body to travel extends across the floors, it is not possible to provide, for example, a fire door for isolating an upper floor from a lower floor to prevent a fire from spreading during a fire, in the floor surface of the floor. As a result, it is necessary to additionally provide fire prevention equipment for preventing a fire from spreading, which causes a problem that the article transport facility becomes even more massive.

Accordingly, example embodiments of the present invention provide inter-floor transport devices to transport an article between a plurality of floors with a simple structure, and can be installed in a small floor area, and an inter-floor transport system that includes the same.

An inter-floor transport device that transports an article between a plurality of floors separated in an up-down direction, and includes a lifting base to support the article to be transported, a plurality of suspenders to suspend the lifting base, and a lifting device that is installed above the lifting base to raise the lifting base from a floor on a lower side to a floor on an upper side or lower the lifting base from the floor on the upper side to the floor on the lower side through an opening in a floor surface of the floor by winding up or unwinding the suspenders.

According to an example embodiment of the present invention configured as above, since the lifting base is suspended by the suspenders, and the lifting base is raised or lowered through the opening in the floor surface of the floor by the lifting device, it is not necessary to provide a structure such as a guide rail through the opening in the floor surface, and it is possible to transport the article between the plurality of floors with the simple structure. Further, since a rail or the like that extends through the opening in the floor surface is not required, it is possible to reduce the size of the opening, and it is possible to install the inter-floor transport device in the small floor area.

In an example embodiment of the present invention, it is preferable to further include an abutment that is provided to be adjacent to a track where the lifting base rises and lowers, the lifting base includes a restrictor to restrict movement in a lateral direction of the lifting base, and the restrictor is movable between an abutment position at which the restrictor abuts on the abutment to restrict movement in the lateral direction of the lifting base, and a non-abutment position that is spaced away from the abutment.

According to an example embodiment of the present invention configured as above, since the restrictor is moved between the abutment position where it abuts on the abutment to restrict movement in the lateral direction of the lifting base and the non-abutment position, it is possible to reduce or prevent sway of the lifting base when movement in the lateral direction of the lifting base is desired to be reduced or prevented at a time of loading and unloading of the article to and from the lifting base and the like.

In an example embodiment of the present invention, it is preferable to further include a fire door configured to close the opening between the two floors.

According to an example embodiment of the present invention configured as above, since the fire door that closes the opening configured to allow the two floors to communicate with each other is included, it is possible to prevent a fire from spreading through the opening during a fire. That is to say, according to an example embodiment of the present invention, since the structure such as a rail extending through the opening and the fire door do not interfere with each other, it is possible to easily close the opening with the fire door without providing a special mechanism.

Further, an example embodiment of the present invention is an inter-floor transport system that transports an article between a plurality of floors overlapping in an up-down direction, and includes the inter-floor transport device according to another example embodiment of the present invention, and a first carrier vehicle to move the article transported by the inter-floor transport device within one floor, wherein the first carrier vehicle includes a transfer device to receive the article from the lifting base of the inter-floor transport device, and a traveling device for the first carrier vehicle to move within a floor in which the first carrier vehicle is installed.

According to an example embodiment of the present invention configured as above, since the first carrier vehicle that moves the article transported by the inter-floor transport device within the one floor is included, it is possible to easily transport the article transported by the inter-floor transport device within the floor of the transport destination.

In an example embodiment of the present invention, it is preferable that the transfer device of the first carrier vehicle includes a lifting table to place the article transported by the inter-floor transport device thereon, and when receiving the article from the lifting base of the inter-floor transport device, the first carrier vehicle moves to below the lifting base, thereafter, raises the lifting table through a cutout in the lifting base, and supports the article placed on the lifting base, on the lifting table.

According to an example embodiment of the present invention configured as above, since the transfer device of the first carrier vehicle includes the lifting table, and it is possible to support the article on the lifting table by raising the lifting table through the cutout of the lifting base, it is possible to transfer the article to and from the lifting base by the lifting table capable of only a simple up-and-down movement.

In an example embodiment of the present invention, it is preferable to further include a second carrier vehicle that moves above the first carrier vehicle, within a same floor as the first carrier vehicle, the second carrier vehicle being movable on a pair of rails that are laid above the first carrier vehicle, wherein when the second carrier vehicle receives an article from the inter-floor transport device, the second carrier vehicle moves to below the lifting base of the inter-floor transport device along the pair of rails, whereas when the first carrier vehicle receives an article from the inter-floor transport device, the second carrier vehicle retracts from the track of the lifting base of the inter-floor transport device, and the inter-floor transport device lowers the lifting base through between the pair of rails to transfer the article to the first carrier vehicle that is moved to below the lifting base.

According to an example embodiment of the present invention configured as above, since the first carrier vehicle, and the second carrier vehicle that moves on the rail that is laid above the first carrier vehicle are included, it is possible to transfer the article at two spots within one floor, from the lifting base capable of only moving in the up-down direction, and it is possible to improve transport efficiency of the article by the inter-floor transport system.

In an example embodiment of the present invention, it is preferable to further include a ceiling travel vehicle installed on the same floor as the first carrier vehicle and the second carrier vehicle, the ceiling travel vehicle being configured to move to a predetermined reception position and receive articles moved by the first carrier vehicle and the second carrier vehicle, wherein when receiving the article from the first carrier vehicle, the ceiling travel vehicle moves to the reception position, and receives the article moved by the first carrier vehicle from above, and when receiving the article from the second carrier vehicle, the ceiling travel vehicle moves to the reception position, and receives the article moved by the second carrier vehicle from a side.

According to an example embodiment of the present invention configured as above, since the ceiling travel vehicle that receives the article moved by the first carrier vehicle and the second carrier vehicle is included, it is possible to transport the article efficiently within the floor. Further, since the ceiling travel vehicle can receive the article moved by the first carrier vehicle and the second carrier vehicle in the same reception position, it is possible to transfer the article to the ceiling travel vehicle from the respective transport vehicles in a small space.

According to the inter-floor transport devices of example embodiments of the present invention, and the inter-floor transport systems including the same, it is possible to transport an article between a plurality of floors with a simple structure, and it is possible to install the device in a small floor area.

The above and other elements, features, steps, characteristics and advantages of the present invention will become more apparent from the following detailed description of the example embodiments with reference to the attached drawings.

### BRIEF DESCRIPTION OF THE DRAWINGS

FIG. 1 is a side view showing an entire inter-floor transport system according to an example embodiment of the present invention.

FIG. 2 is a front view showing an entire inter-floor transport system according to an example embodiment of the present invention.

FIG. 3 is an enlarged side view showing a lifting device included in an inter-floor transport device according to an example embodiment of the present invention.

FIG. 4 is an enlarged top view showing the lifting device included in an inter-floor transport device according to an example embodiment of the present example embodiment.

FIG. 5 is a side view showing a state in which a restrictor included in a sway suppression mechanism of a lifting base is in a non-abutment position, in an inter-floor transport device according to an example embodiment of the present invention.

FIG. 6 is a top view showing a state in which the restrictor included in the lifting base is in the non-abutment position, in an inter-floor transport device according to an example embodiment of the present invention.

FIG. 7 is a side view showing a state in which the restrictor included in the lifting base is in an abutment position, in an inter-floor transport device according to an example embodiment of the present invention.

FIG. 8 is a top view showing the state in which the restrictor included in the lifting base is in the abutment position, in an inter-floor transport device according to an example embodiment of the present invention.

FIG. 9 is an enlarged side view showing a portion in which a first carrier vehicle, a second carrier vehicle, and a ceiling travel vehicle are provided adjacently to the inter-floor transport device, in an inter-floor transport system of an example embodiment of the present invention.

FIG. 10 is an enlarged front view showing a portion in which the first carrier vehicle, and the second carrier vehicle are provided adjacently to the inter-floor transport device, in an inter-floor transport system of an example embodiment of the present invention.

FIG. 11 is a side view showing a state in which an article is being lowered from the ceiling travel vehicle onto the second carrier vehicle, in an inter-floor transport system of an example embodiment of the present invention.

FIG. 12 is a side view showing a state in which an article is lowered from the ceiling travel vehicle onto the first carrier vehicle, in an inter-floor transport system of an example embodiment of the present invention.

### DETAILED DESCRIPTION OF THE EXAMPLE EMBODIMENTS

Next, with reference to the accompanying drawings, inter-floor transport devices according to example embodiments of the present invention, and inter-floor transport systems including the same will be described.

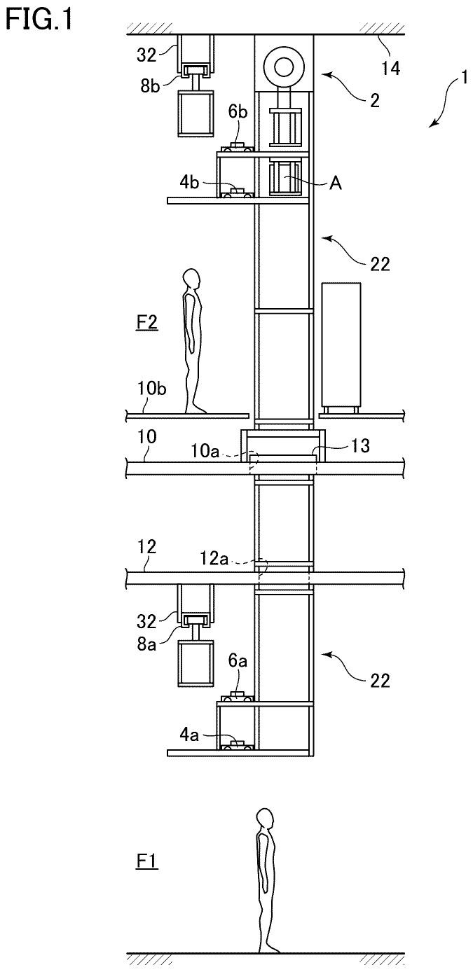

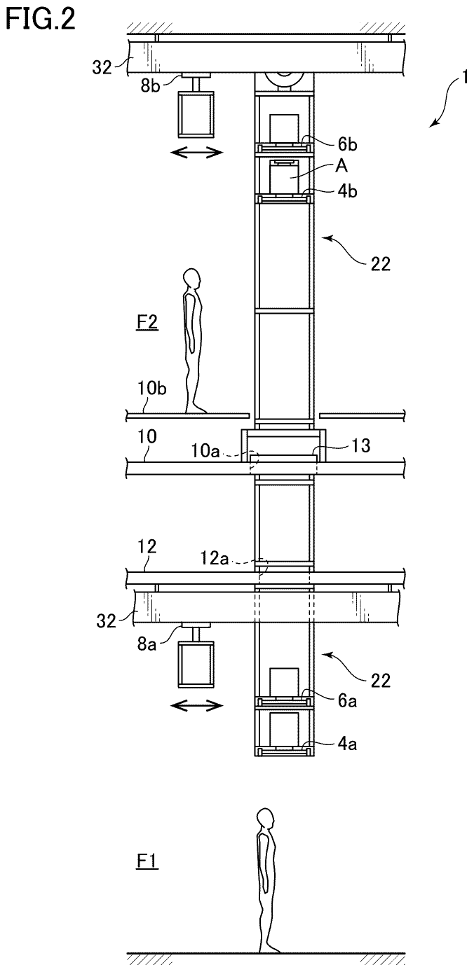

FIG. 1 is a side view showing an entire inter-floor transport system according to an example embodiment of the present invention. FIG. 2 is a front view showing an entire inter-floor transport system according to an example embodiment of the present invention.

As shown in FIG. 1 and FIG. 2, an inter-floor transport system 1 according to an example embodiment of the present invention includes an inter-floor transport device 2, first carrier vehicles 4a and 4b, second carrier vehicles 6a and 6b, and ceiling travel vehicles 8a and 8b, and is configured to transport an article A between a first floor F1 and a second floor F2. In the present example embodiment, the first floor F1 and the second floor F2 are a first floor and a second floor of a same building, are separated in an up-down direction, and are positioned so as to overlap in the up-down direction. Further, in the present example embodiment, the article A that is transported by the inter-floor transport system 1 is a font opening unified pod (FOUP) accommodating a semiconductor substrate, for example.

Here, in the present example embodiment, openings 10a and 12a are respectively formed in a floor surface 10 of the second floor F2, and a ceiling surface 12 of the first floor F1. The article A that is transported between the floors by the inter-floor transport device 2 is raised from the first floor F1 to the second floor F2 through these openings 10a and 12a, or lowered from the second floor F2 to the first floor F1. Further, in the present example embodiment, a grating 10b that is a lattice made of metal is provided above the floor surface 10 of the second floor F2, and a worker and the like on the second floor F2 walk on the grating 10b.

Further, the floor surface 10 is provided with a fire door 13 to close the opening 10a in the event of a fire or the like. This fire door 13 closes the opening 10a that is an opening to allow the first floor F1 and the second floor F2 to communicate with each other, and thus can prevent a fire from spreading between the respective floors through the opening 10a. That is to say, during a normal operation time of the inter-floor transport device 2, the fire door 13 is opened, and the lifting base 16 is allowed to be lifted and lowered through the opening 10a. When a fire is detected on the first floor F1 or the second floor F2 by a fire detector (not illustrated) or the like, the lifting base 16 is moved more upward than the fire door 13 and then the fire door 13 is closed to prevent a fire from spreading. In the inter-floor transport device 2 of the present example embodiment, since a rail or a column that extends through the opening 10a is not provided, it is possible to easily close the opening 10a by the fire door 13.

Furthermore, in the inter-floor transport system 1 of the present example embodiment, when the article A is transported from the first floor F1 to the second floor F2, the article A transported by the ceiling travel vehicle 8a included in the first floor F1 is received by the first carrier vehicle 4a, and this article A is transported to the second floor F2 by the inter-floor transport device 2. Furthermore, the article A transported to the second floor F2 by the inter-floor transport device 2 is received by the second carrier vehicle 6b included in the second floor F2. Next, this article A is received by the ceiling travel vehicle 8b included in the second floor F2, and is transported within the second floor F2.

On the other hand, when the article A is transported from the second floor F2 to the first floor F1, the article A transported by the ceiling travel vehicle 8b included in the second floor F2 is received by the first carrier vehicle 4b, and this article A is transported to the first floor F1 by the inter-floor transport device 2. Further, the article A transported to the first floor F1 by the inter-floor transport device 2 is received by the second carrier vehicle 6a included in the first floor F1. Next, this article A is received by the ceiling travel vehicle 8a included in the first floor F1, and is transported within the first floor F1.

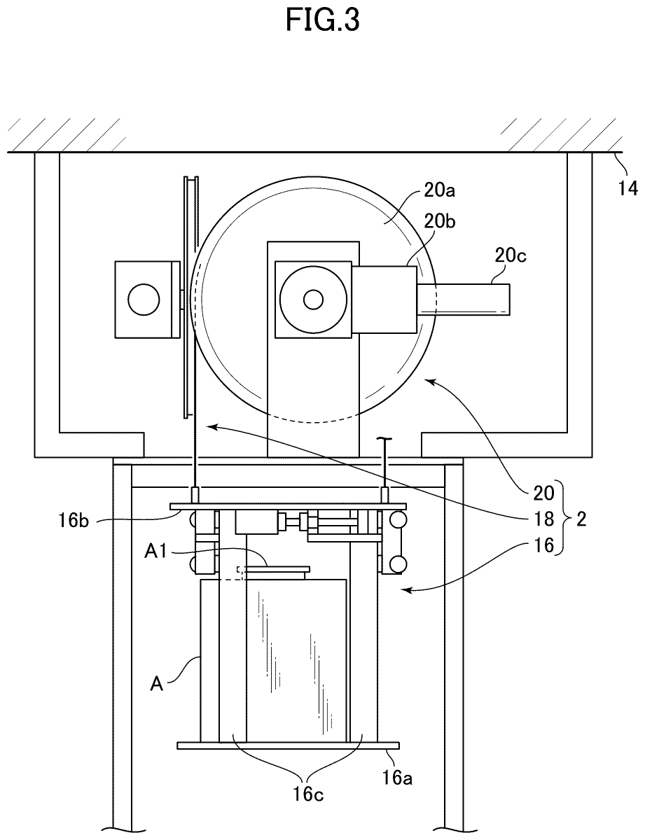

Next, with reference to FIG. 3 to FIG. 8, a configuration of the inter-floor transport device 2 according to an example embodiment of the present invention will be described.

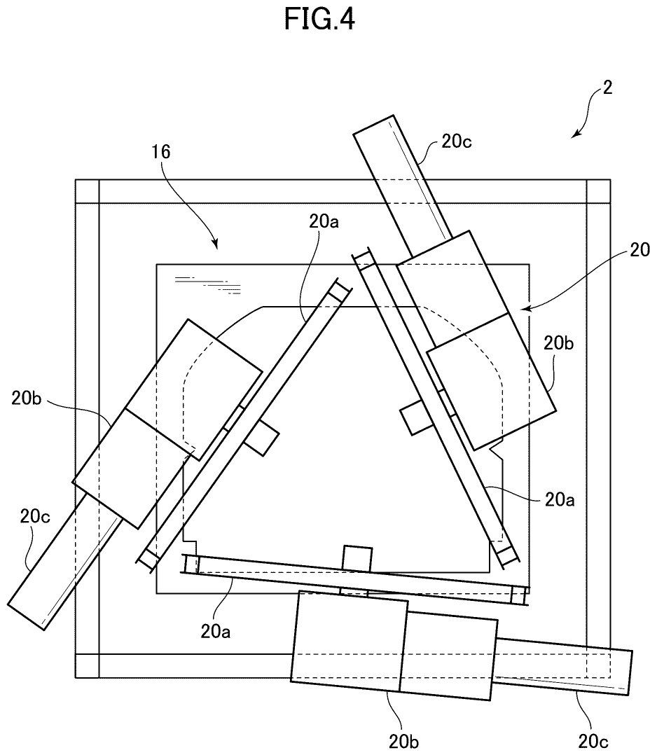

First, with reference to FIG. 3 and FIG. 4, a mechanism to lift and lower the lifting base of the inter-floor transport device 2 will be described.

FIG. 3 is an enlarged side view showing a lifting device included in the inter-floor transport device 2 according to an example embodiment of the present invention. FIG. 4 is an enlarged top view showing the lifting device included in the inter-floor transport device 2 according to an example embodiment of the present invention.

As shown in FIG. 3, the inter-floor transport device 2 of the present example embodiment is attached to a ceiling surface 14 of the second floor F2, and includes the lifting base 16 to support an article to be transported, three belts 18 that are suspenders to suspend this lifting base 16 from above, a lifting device 20 to raise and lower the lifting base 16 by winding up or unwinding the belts 18. Note that in the present example embodiment, the second floor F2 is an uppermost floor to which the inter-floor transport device 2 transports articles.

The lifting base 16 supports the article A to be transported by placing the object A thereon, and includes a bottom plate 16a to place the article A, a top plate 16b to which the belts 18 are attached, and a plurality of connection plates 16c that connect the bottom plate 16a and the top plate 16b. The bottom plate 16a is a flat plate that is oriented in a horizontal direction, and the article A is placed thereon. The top plate 16b is a flat plate that is oriented in parallel with the bottom plate 16a, above the bottom plate 16a, and the belts 18 are fixed to an upper surface thereof. The connection plates 16c are each an elongated plate extending in a vertical direction so as to connect the bottom plate 16a and the top plate 16b, and the plurality of connection plates 16c are provided. Accordingly, the article A supported by the lifting base 16 is accommodated in a space surrounded by the bottom plate 16a, the top plate 16b, and the plurality of connection plates 16c.

Note that in the present example embodiment, the article A is supported by placing the article A on the bottom plate 16a of the lifting base 16, but example embodiments of the present invention can also be configured so as to support the article A by suspending it from the lifting base 16 by engaging an engagement portion provided at the article A with the lifting base 16, for example.

As shown in FIG. 3, the lifting device 20 includes a drum 20a in a disk shape on which the belts 18 are wound, a motor 20c to drive this drum 20a, and a speed reducer 20b to rotate the drum 20a by decreasing a rotational speed of an output shaft (not illustrated) of the motor 20c. Further, the lifting device 20 is fixed to the ceiling surface 14 of the second floor F2, and the lifting base 16 is suspended from this lifting device 20 via the three belts 18. As shown in FIG. 4, in the present example embodiment, the lifting device 20 includes three sets of drums 20a, speed reducers 20b, and motors 20c, and can wind up and unwind the three belts 18 by rotationally driving the respective drums 20a.

Further, in the present example embodiment, the respective drums 20a are disposed such that central axes thereof extend in the horizontal direction and define an angle of about 120 degrees with each other in top view, and the three drums 20a in the disk shape are positioned to define a substantially regular triangle. Accordingly, the respective belts 18 that are unwound from the respective drums 20a extend vertically downward from positions of three apexes of the regular triangle, and lower ends thereof are respectively fixed to the upper surface of the top plate 16b of the lifting base 16. Consequently, it is possible to adjust the posture of the lifting base 16 suspended by the three belts 18 by unwinding amounts of the respective belts 18. Furthermore, in the present example embodiment, since the respective belts 18 are positioned to define the angle (unparallel) with each other, the respective belts 18 can resist any movement in a lateral direction of the lifting base 16, and can reduce or prevent sway of the lifting base 16.

Furthermore, in the present example embodiment, the lifting device 20 is equipped with an angle sensor (not illustrated) that detects an inclination of the lifting base 16. The inclination of the lifting base 16 is detected by this angle sensor (not illustrated), and winding amounts and unwinding amounts of the respective belts 18 are adjusted by feedback control SO that the lifting base 16 is maintained horizontally. Alternatively, a rotary encoder (not illustrated) to detect rotation of the respective drums 20a are provided, and it is also possible to control the posture of the lifting base 16 by adjusting the winding amounts and the unwinding amounts of the respective belts 18 based on this. Further, by performing teaching on the position where the article A is transferred from the lifting base 16, the lifting base 16 can also be adjusted horizontally.

Note that in the present example embodiment, the lifting base 16 is suspended by the belts 18, but besides the belts, any structures that can suspend the lifting base 16, such as wire ropes, and chains can be used as the suspender. Further, in the present example embodiment, the lifting base 16 is suspended by the three belts 18, but the lifting base 16 can be suspended by any multiple suspenders.

As above, the inter-floor transport device 2 of the present example embodiment can raise and lower the lifting base 16 along a track in the vertical direction through the opening 10a in the floor surface 10 by actuating the respective motors 20c of the lifting device 20.

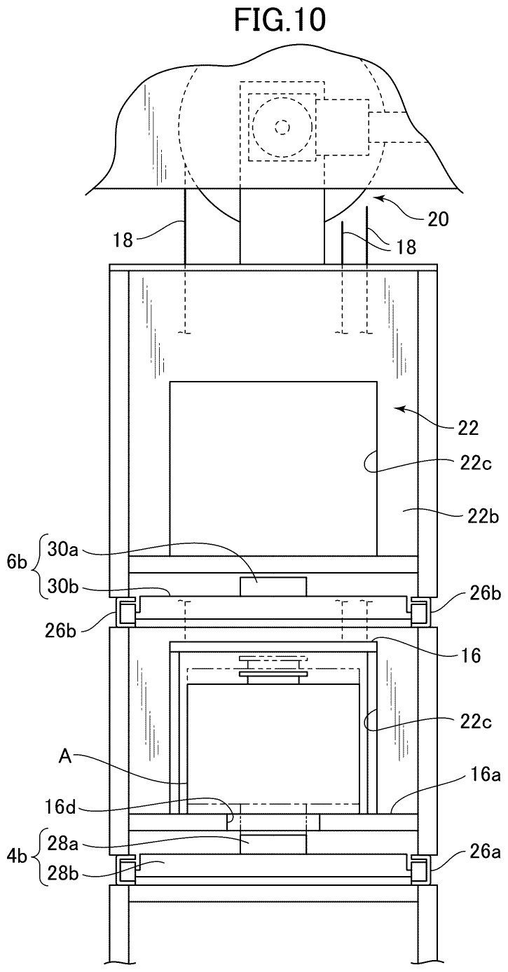

Furthermore, as shown in FIG. 1 and FIG. 2, a cover 22 having a substantially square shape in section is provided to surround the track in the vertical direction through which the lifting base 16 passes. This cover 22 extends from a lower end of the lifting device 20 to a vicinity of the grating 10b of the second floor F2, and from a lower side of the floor surface 10 of the second floor F2 to a vicinity of a middle of the first floor F1, so as to surround a periphery of a portion where the lifting base 16 passes. Note that in the present example embodiment, the cover 22 is not provided from a lower side of the grating 10b to the floor surface 10. Furthermore, in portions of respective ports where loading and unloading of the article A are performed between the lifting base 16, and the first and the second carrier vehicles, opening portions 22c (FIG. 10) are provided in the cover 22, and loading and unloading of the article A can be performed without interference between the article A and the carrier vehicles, and the cover 22.

This cover 22 is provided for the purpose of preventing the lifting base 16 passing through the respective floors from colliding with an obstacle (not illustrated) or the like placed on the floor. Further, the cover 22 can also be provided for the purpose of restraining air from abruptly flowing from a floor with a high atmospheric pressure to a floor having a low atmospheric pressure when the atmospheric pressures of the first floor F1 and the second floor F2 are different, in a semiconductor manufacturing facility or the like. Furthermore, in this case, it is also possible to provide a shutter (not illustrated) so as to open and close the opening portion 22c (FIG. 10) provided in the cover 22. Note that in the present example embodiment, since a weight of the lifting base 16 is not supported by the cover 22, the cover 22 may have minimum strength. Therefore, the cover 22 can be configured in a small size with a light weight, and does not occupy a large floor area. Note that depending on the environment in which the inter-floor transport device 2 is installed, the cover 22 can also be omitted.

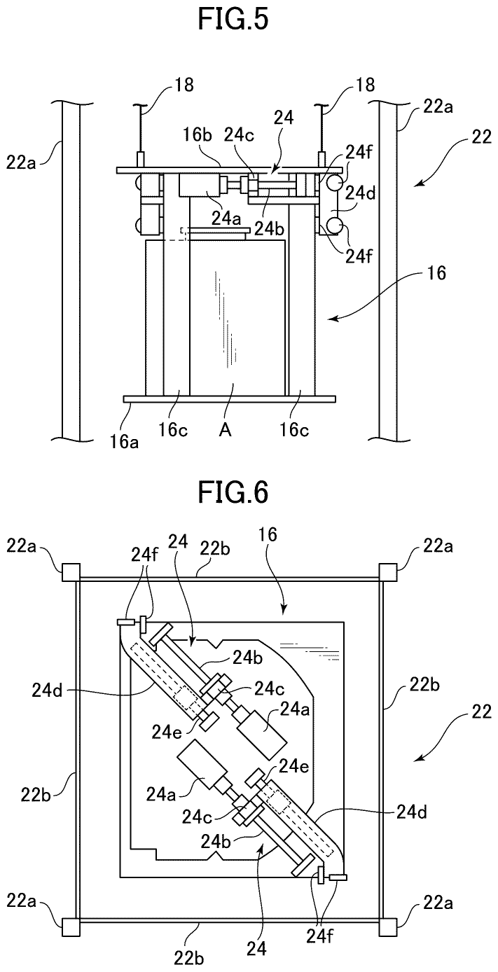

Next, with reference to FIG. 5 to FIG. 8, a sway suppression mechanism to reduce or prevent lateral sway of the lifting base 16 of the inter-floor transport device 2 will be described.

FIG. 5 to FIG. 8 are views for explaining the sway suppression mechanism included in the lifting base 16 of the inter-floor transport device 2 according to an example embodiment of the present invention. Here, a restrictor included in the sway suppression mechanism is configured to be movable between an abutment position and a non-abutment position.

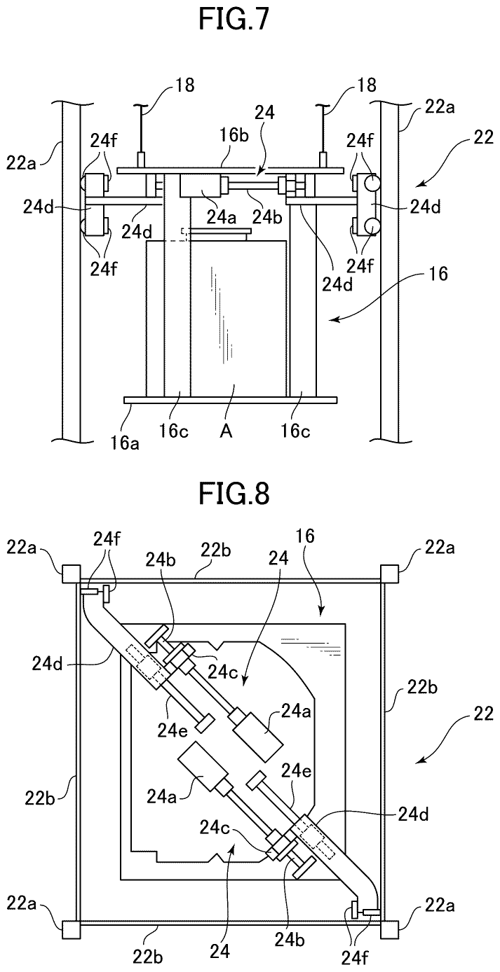

FIG. 5 is a side view showing a state in which the restrictor included in the sway suppression mechanism of the lifting base 16 is in the non-abutment position. FIG. 6 is a top view showing a state in which the restrictor included in the lifting base 16 is in the non-abutment position. FIG. 7 is a side view showing a state in which the restrictor included in the lifting base 16 is in the abutment position. FIG. 8 is a top view showing a state in which the restrictor included in the lifting base 16 is in the abutment position. Note that FIG. 6 and FIG. 8 show the sway suppression mechanism in a state in which the top plate 16b of the lifting base 16 is removed.

As shown in FIG. 5, a sway suppression mechanism 24 to reduce or prevent lateral sway of the lifting base 16 is provided at a lower side of the top plate 16b of the lifting base 16.

As shown in FIG. 6, two sway suppression mechanisms 24 are provided in the lifting base 16, and the sway suppression mechanisms 24 are configured to let the restrictors out in a direction of a diagonal line of the lifting base 16, respectively, when reducing or preventing lateral sway of the lifting base 16. Note that the two sway suppression mechanisms 24 provided at the lifting base 16 have a same configuration.

As shown in FIG. 6, the respective sway suppression mechanisms 24 each have a motor 24a, a ball screw shaft 24b that is rotationally driven by this motor 24a, and a ball screw nut 24c that is screwed onto the ball screw shaft 24b. Furthermore, the respective sway suppression mechanisms 24 each have an arm 24d, a linear guide 24e that supports this arm 24d slidably in the direction of the diagonal line of the lifting base 16, and a guide roller 24f attached to a tip portion of the arm 24d. Here, in the present example embodiment, the restrictor to restrict movement in the lateral direction of the lifting base 16 is configured by the arm 24d, and the guide roller 24f attached to a tip portion thereof.

The ball screw shaft 24b is a feed screw to advance the ball screw nut 24c that is screwed thereon, is oriented in the horizontal direction at a lower side of the top plate 16b of the lifting base 16, and is rotatably supported. £ Furthermore, the ball screw shaft 24b is oriented in the direction of substantially the diagonal line of the lifting base 16 in top view. This ball screw shaft 24b is connected to the motor 24a and is rotationally driven by the motor 24a. Accordingly, the ball screw nut 24c is advanced on the ball screw shaft 24b.

Furthermore, the arm 24d preferably has an elongated plate shape, and four guide rollers 24f are attached to a tip portion thereof. The arm 24d is slidably supported in a longitudinal direction by the linear guide 24e, and can smoothly move. Furthermore, the linear guide 24e is attached parallel with the ball screw shaft 24b, and is configured to guide the arm 24d parallel with the ball screw shaft 24b. Further, a base end portion of the arm 24d is connected to the ball screw nut 24c, and when the ball screw nut 24c is advanced by the ball screw shaft 24b, the arm 24d is slid along with this. Accordingly, the restrictor including the arm 24d and the guide rollers 24f is moved in the direction of the diagonal line of the lifting base 16, and is configured to be movable between the non-abutment position shown in FIG. 6 and the abutment position shown in FIG. 8.

On the other hand, the cover 22 (FIG. 1) that is configured to surround the track of the lifting base 16 includes four channel materials 22a disposed at four corners of the cover 22, and a thin plate material 22b that is attached so as to connect them. The channel material 22a preferably has an elongated rod shape, and is provided to extend in the vertical direction around the lifting base 16. Further, the plate material 22b preferably has a thin plate shape that is attached to the channel materials 22a so as to connect the respective channel materials 22a respectively. Accordingly, a space in a substantially square shape in top view is defined by the four plate materials 22b around the lifting base 16.

Here, when the motor 24a of the sway suppression mechanism 24 is actuated, the arm 24d is advanced in the direction of the diagonal line of the lifting base 16 from the non-abutment position shown in FIG. 6, and is moved to the abutment position shown in FIG. 8. In this state, the respective arms 24d extend to two corners facing each other in the direction of the diagonal line of the cover 22, and the guide rollers 24f attached to the tip portions of the respective arms 24d respectively abut on the cover 22.

Specifically, two pairs of guide rollers 24f, a total of four guide rollers 24f are rotatably attached to the tip portion of each of the arms 24d, and the guide rollers 24f of each of the pairs are disposed side by side in the vertical direction (FIG. 5). Central axes of the guide rollers 24f of each of the pairs are oriented parallel with each other, and the central axes of the guide rollers 24f of one of the pairs are oriented to define a right angle with respect to central axes of the guide rollers 24f of the other pair.

As shown in FIG. 8, in a state in which the arm 24d of the sway suppression mechanism 24 is advanced, the guide rollers 24f of the respective pairs respectively abut onto the two adjacent plate materials 22b at the corner portion of the cover 22. Accordingly, the respective guide rollers 24f provided at the tip portion of the arm 24d respectively abut on the two plate materials 22b that are adjacent in the corner portion of the cover 22 to which the arm 24d extends. Since the two arms 24d respectively extend toward corner portions that face each other, of the cover 22, the guide rollers 24f abut on all of the four plate materials 22b that form the cover 22.

Accordingly, in the present example embodiment, the respective plate materials 22b function as abutments that abut on the restrictors (each including the arm 24d and the guide rollers 24f). In this way, the restrictor (arm 24d and the guide rollers 24f) is spaced away from the abutment (plate material 22b) in the state of being located in the non-abutment position shown in FIG. 6. On the other hand, when the restrictor is moved to the abutment position shown in FIG. 8, it abuts on the abutment and restricts movement in the lateral direction of the lifting base.

That is to say, the guide rollers 24f attached to the arm 24d that extends from the lifting base 16 abut on the plate materials 22b of the cover 22 fixed to the periphery of the lifting base 16, such that the movement in the lateral direction of the lifting base 16 that is suspended by the belts 18 is restricted, and sway of the lifting base 16 is reduced or prevented. Further, since the guide rollers 24f attached to the arm 24d contact the plate materials 22b, movement in the vertical direction of the lifting base 16 is allowed even in the state in which the guide rollers 24f and the plate material 22b abut on each other. Note that in the present example embodiment, the plate materials 22b of the cover 22 fixed to the periphery of the lifting base 16 function as the abutments, but the abutments may be provided at only a spot where the movement in the lateral direction of the lifting base 16 is desired to be restricted, and any structure that is fixed to the position abutting on the restrictor can be used as the abutment.

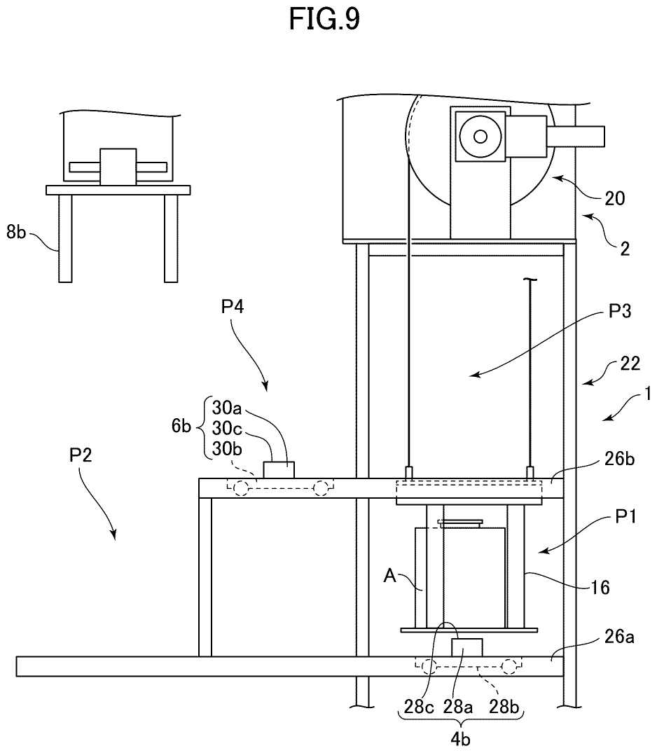

Next, with reference to FIG. 9 and FIG. 10, carrier vehicles included in the inter-floor transport system 1 according to an example embodiment of the present invention will be described.

The inter-floor transport system 1 of the present example embodiment includes the first carrier vehicle and the second carrier vehicle that move the article A that is transported by the inter-floor transport device 2 within one floor.

FIG. 9 is an enlarged side view showing portions in which the first carrier vehicle 4b, the second carrier vehicle 6b, and the ceiling travel vehicle 8b are provided adjacently to the inter-floor transport device 2, in the inter-floor transport system 1 of the present example embodiment. FIG. 10 is an enlarged front view showing portions in which the first carrier vehicle 4b, and the second carrier vehicle 6b are provided adjacently to the inter-floor transport device 2, in the inter-floor transport system 1 of the present example embodiment. Note that FIG. 9 and FIG. 10 show the first carrier vehicle 4b, the second carrier vehicle 6b, and the ceiling travel vehicle 8b that are disposed on the second floor F2, and the first carrier vehicle 4a, the second carrier vehicle 6a, and the ceiling travel vehicle 8a that are disposed on the first floor F1 are similarly configured.

As shown in FIG. 9, the first carrier vehicle 4b is configured to travel along a pair of first rails 26a extending in the horizontal direction, and the second carrier vehicle 6b is configured to travel along a pair of second rails 26b extending in the horizontal direction of the second carrier vehicle 6b. The first rail 26a extends from a first port P1 where unloading of the article A is performed between the lifting base 16 and the first carrier vehicle 4b to a second port P2 where unloading of the article A is performed between the first carrier vehicle 4b and the ceiling travel vehicle 8b, and the first carrier vehicle 4b can move in the horizontal direction between the first port P1 and the second port P2. In the present example embodiment, the first port Pl is positioned on the track where the lifting base 16 moves, and the second port P2 is positioned directly below the track of the ceiling travel vehicle 8b.

Note that spaces between the pair of first rails 26a and the pair of second rails 26b are respectively provided to be wider than a width of the lifting base 16. Therefore, in the state in which no carrier vehicle is in the port where the unloading of the article A is performed, the lifting base 16 can freely pass through the respective ports in the vertical direction through the spaces of the pairs of first rails 26a and the second rails 26b.

On the other hand, the second rail 26b where the second carrier vehicle 6b travels is disposed more upward than the first rail 26a, so that the first carrier vehicle 4b on which the article A is placed can travel on a lower side of the second rail 26b. Furthermore, the second rail 26b is shorter than the first rail 26a and extends from a third port P3 where unloading of the article A is performed between the lifting base 16 and the second carrier vehicle 6b to a fourth port P4 where unloading of the article A is performed between the second carrier vehicle 6b and the ceiling travel vehicle 8b. The second carrier vehicle 6b can move in the horizontal direction between the third port P3 and the fourth port P4. The third port P3 is positioned on the track where the lifting base 16 moves, directly above the first port P1. The fourth port P4 is adjacent to the third port P3 and is positioned between the first port P1 and the second port P2 in plan view. The fourth port P4 is located in a position adjacent to the track of the ceiling travel vehicle 8a in plan view. That is to say, the second rail 26b does not extend to directly below the track of the ceiling travel vehicle 8a, and a range in which the second carrier vehicle 6b can move is narrower than a range in which the first carrier vehicle 4b can move.

The first carrier vehicle 4b includes a transfer device 28a that receives the article A from the lifting base 16, and a traveling device 28b to move on the first rail 26a on which the first carrier vehicle 4b is installed. Note that since the first rail 26a is provided on the second floor F2, the traveling device 28b of the first carrier vehicle 4b moves the first carrier vehicle 4b within the second floor F2 in which the first carrier vehicle 4b is installed.

The traveling device 28b of the first carrier vehicle 4b includes four wheels, and by driving these wheels, it can cause the first carrier vehicle 4b to travel along the first rail 26a. On the other hand, as shown in FIG. 10, the pair of first rails 26a respectively have substantially U-shaped sections, and are disposed so that opening portions of the U-shaped sections face each other. Further, each of the wheels included in the traveling device 28b is received inside of the first rail 26a having the U-shaped section, and each of the wheels does not detach from the first rail 26a. Accordingly, the first carrier vehicle 4b can move from the first port P1 to the second port P2.

Next, the transfer device 28a of the first carrier vehicle 4b is provided on an upper side of the traveling device 28b, and includes a lifting table 28c capable of rising and lowering. The lifting table 28c is a table capable of rising and lowering to place the article A thereon, and the transfer device 28a can raise and lower the lifting table 28c in a state in which the article A is placed thereon. By raising/lowering the lifting table 28c in the respective ports where unloading of the article A is performed, it is possible to perform loading of the article A onto the lifting base 16, or reception of the article A from the lifting base 16.

As shown in FIG. 9, for example, when reception of the article A is performed in the first port P1, the first carrier vehicle 4b is caused to travel into the first port P1 in the state in which the lifting table 28c is lowered, after the lifting base 16 with the article A placed thereon stops in the first port P1. Note that since a height of the first carrier vehicle 4b is lower than an undersurface of the lifting base 16 in the state in which the lifting table 28c is lowered, it is possible to move the first carrier vehicle 4b to below the lifting base 16 in the first port P1 without interfering with the lifting base 16 even in the state in which the lifting base 16 is stopping in the first port P1.

Next, the lifting table 28c of the first carrier vehicle 4b is raised. Here, as shown in FIG. 10, a cutout 16d is provided in the bottom plate 16a of the lifting base 16, and the cutout 16d extends to below the article A placed on the bottom plate 16a of the lifting base 16. When the lifting table 28c is raised in the state in which the first carrier vehicle 4b is positioned below the lifting base 16, an upper surface of the lifting table 28c rises to above the bottom plate 16a of the lifting base 16 through the cutout 16d. Accordingly, as shown by an imaginary line in FIG. 10, the article A placed on the bottom plate 16a of the lifting base 16 is lifted up from the bottom plate 16a by the lifting table 28c, and is supported on the lifting table 28c. By retracting the first carrier vehicle 4b from the first port P1 in this state, it is possible to receive the article A from the lifting base 16.

On the other hand, when loading of the article A is performed in the first port P1, the vacant lifting base 16 stops inside the first port P1, and thereafter, the first carrier vehicle 4b is caused to travel into the first port P1 in the state in which the article A is placed on the lifting table 28c that is raised. At this time, the lifting table 28c that is raised is received into the cutout 16d provided in the bottom plate 16a of the lifting base 16, and the article A placed on the lifting table 28c is received between the bottom plate 16a and the top plate 16b of the lifting base 16. Therefore, even in the state in which the lifting base 16 is stopping inside the first port P1, it is possible to advance the first carrier vehicle 4b with the article A placed thereon into the first port P1 without interfering with the lifting base 16. Then, when the lifting table 28c is lowered, a bottom surface of the article A on the lifting table 28c abuts on the bottom plate 16a of the lifting base 16, and the article A is placed on the bottom plate 16a. The first carrier vehicle 4b is retracted from the first port P1 in this state, and thus loading of the article A onto the lifting base 16 from the first carrier vehicle 4b is completed.

Next, the second carrier vehicle 6b is configured to be movable on the pair of second rails 26b that are laid above the first carrier vehicle 4b. This second carrier vehicle 6b similarly includes a transfer device 30a that receives the article A from the lifting base 16, and a traveling device 30b to move on the second rail 26b in which the second carrier vehicle 6b is installed. The transfer device 30a and the traveling device 30b are configured similarly to the transfer device 28a and the traveling device 28b of the first carrier vehicle 4b, respectively. Furthermore, an operation when performing unloading of the article A between the second carrier vehicle 6b and the lifting base 16 in the third port P3 is also similar to the operation of unloading between the first carrier vehicle 4b and the lifting base 16 described above.

That is to say, when the second carrier vehicle 6b receives the article A from the inter-floor transport device 2, the second carrier vehicle 6b moves to below the lifting base 16 of the inter-floor transport device 2 along the second rail 26b, and receives the article A. On the other hand, when the first carrier vehicle 4b receives the article A from the inter-floor transport device 2, the second carrier vehicle 6b retracts from the track of the lifting base 16 (retracts from the third port P3) of the inter-floor transport device 2, and the inter-floor transport device 2 lowers the lifting base 16 through between the pair of second rails 26b and can transfer the article A to the first carrier vehicle 4b that is moved to below the lifting base 16.

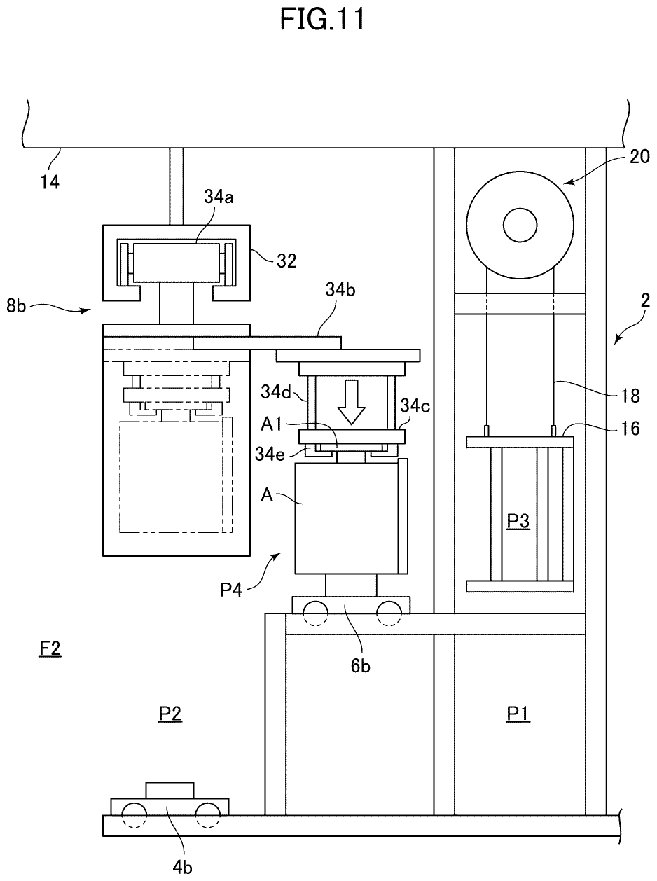

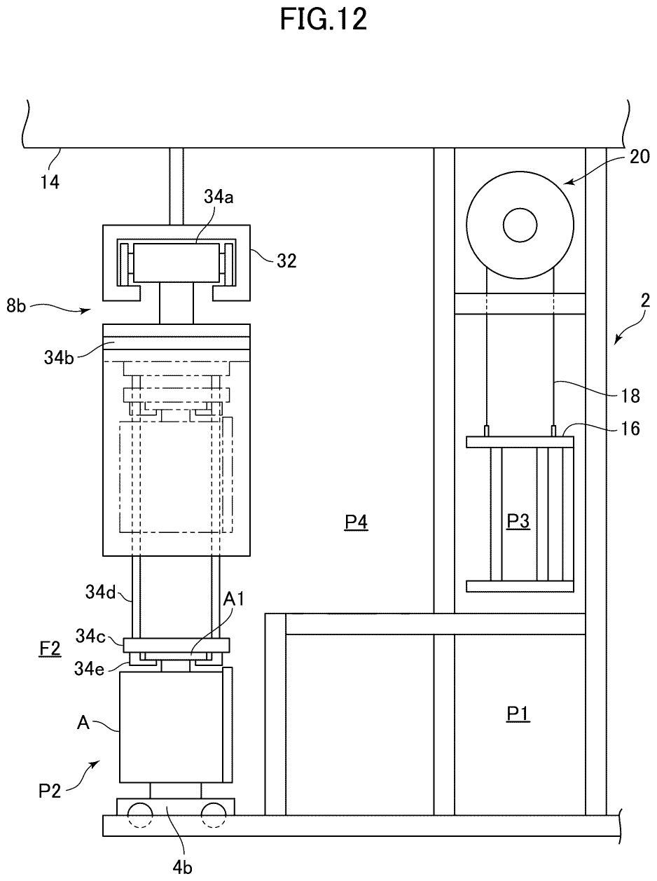

Next, with reference to FIG. 11 and FIG. 12, a configuration of the ceiling travel vehicle included in the inter-floor transport system 1 will be described.

The ceiling travel vehicle is installed on the same floor as the first carrier vehicle 4b, and the second carrier vehicle 6b, and is configured to move to a predetermined reception position to receive the article A moved by the first carrier vehicle 4b and the second carrier vehicle 6b.

FIG. 11 is a side view showing a state in which the article is lowered onto the second carrier vehicle from the ceiling travel vehicle. FIG. 12 is a side view showing a state in which the article is lowered onto the first carrier vehicle from the ceiling travel vehicle. Note that hereinafter, a configuration and an operation of the ceiling travel vehicle 8b installed on the second floor F2 will be described, and a configuration, and an operation of the ceiling travel vehicle 8a installed on the first floor F1 are all the same.

As shown in FIG. 11, the ceiling travel vehicle 8b includes a traveling mechanism 34a, a slide mechanism 34b, a grasping mechanism 34c, a suspension belt 34d, and a gripper 34e, and is configured to travel in a state in which it is suspended from a rail 32 laid on the ceiling surface 14.

The ceiling travel vehicle 8b is configured to travel by wheels included in the traveling mechanism 34a and to be able to move to a position to be a target along the rail 32. Note that in the present example embodiment, the ceiling travel vehicle 8b is configured to travel in a direction perpendicular to the paper surfaces of FIG. 11 and FIG. 12.

The slide mechanism 34b is configured to be able to extend and contract in the horizontal direction by a ball screw drive mechanism (not illustrated), is extended to above the fourth port P4 when unloading of the article A is performed in the fourth port P4, and is contracted to below the traveling mechanism 34a when the ceiling travel vehicle 8b travels.

The grasping mechanism 34c is attached to a tip of the slide mechanism 34b, and is configured to grasp a flange A1 provided at the article A. Specifically, the gripper 34e is provided at an undersurface of the grasping mechanism 34c, the gripper 34e opens and closes, and thus it can hold the flange A1 of the article A.

The suspension belt 34d is configured to suspend the grasping mechanism 34c from the slide mechanism 34b, and four suspension belts 34d are included in the one ceiling travel vehicle 8b. Furthermore, the suspension belts 34d are each wound around a reel (not illustrated) provided at the tip of the slide mechanism 34b, and by rotationally driving the reel, the grasping mechanism 34c can be moved up and down via the suspension belts 34d.

When the article A is lowered onto the second carrier vehicle 6b from the ceiling travel vehicle 8b, the ceiling travel vehicle 8b is firstly stopped at a position adjacent to the fourth port P4 (directly above the second port P2 in FIG. 11). Next, the slide mechanism 34b is extended to move the grasping mechanism 34c grasping the article A to a position directly above the second carrier vehicle 6b that is stopping in the fourth port P4. Furthermore, the grasping mechanism 34c is lowered by unwinding the suspension belts 34d from the slide mechanism 34b, and the article A grasped by the grasping mechanism 34c is placed on the second carrier vehicle 6b. Then, in the state in which the article A is placed on the second carrier vehicle 6b, the gripper 34e is opened to release holding of the flange A1 of the article A.

On the other hand, when the article A transported by the second carrier vehicle 6b is received by the ceiling travel vehicle 8b and transported, the grasping mechanism 34c that does not grasp the article A is lowered from above the article A placed on the second carrier vehicle 6b, and the flange A1 of the article A is held by the gripper 34e. Then, the suspension belts 34d are wound up to raise the grasping mechanism 34c, and the article A is lifted. Further, the slide mechanism 34b is contracted to move the article A grasped by the grasping mechanism 34c to below the traveling mechanism 34a of the ceiling travel vehicle 8b. Thereafter, the ceiling travel vehicle 8b is caused to travel along the rail 32 to transport the article A inside the second floor F2. In this way, when the article A is received from the second carrier vehicle 6b, the ceiling travel vehicle 8b moves to a reception position (directly above the second port P2 in FIG. 11) to receive the article A which is moved by the second carrier vehicle 6b, from a side.

Next, an operation when loading and unloading the article A between the ceiling travel vehicle 8b of the second floor F2 and the first carrier vehicle 4b will be described. When loading and unloading the article A to and from the first carrier vehicle 4b, the ceiling travel vehicle 8b is stopped at a reception position vertically above the second port P2. As shown in FIG. 12, the second port P2 where the first carrier vehicle 4b stops is positioned directly below the rail 32 of the ceiling travel vehicle 8b, and therefore it is possible to raise and lower the grasping mechanism 34c to load and unload the article A between the ceiling travel vehicle 8b and the first carrier vehicle 4b without extending the slide mechanism 34b. In this way, when the article A is received from the first carrier vehicle 4b, the ceiling travel vehicle 8b moves to the reception position, and receives the article A which is moved by the first carrier vehicle 4b, from above. That is to say, the ceiling travel vehicle 8b can transfer the article A between the ceiling travel vehicle 8b and the first carrier vehicle 4b and between the ceiling travel vehicle 8b and the second carrier vehicle 6b in the state in which the ceiling travel vehicle 8b stops at the same reception position (vertically above the second port P2 in FIG. 11 and FIG. 12).

Next, an operation of the inter-floor transport system 1 according to an example embodiment of the present invention will be described.

First, when the article A is transported from the first floor F1 to the second floor F2, the article A transported by the ceiling travel vehicle 8a of the first floor F1 is placed on the first carrier vehicle 4a stopping in the second port P2 of the first floor F1.

On the other hand, in the first port Pl of the first floor F1, the lifting base 16 of the inter-floor transport device 2 is stopped in the state in which the article A is not placed thereon. Further, after the lifting base 16 is stopped in the first port P1, the respective arms 24d of the sway suppression mechanism 24 thereof are respectively unwound in the direction of the diagonal line of the lifting base 16, and the guide rollers 24f attached to the tip portions of the arms 24d are respectively caused to abut on the plate materials 22b of the cover 22. In this way, the restrictors are moved to the abutment positions where they abut on the plate materials 22b that are the abutments, and thus lateral sway of the lifting base 16 when transferring the article A is reduced or prevented.

Next, the first carrier vehicle 4a on which the article A is placed is caused to travel to the first port P1. When the first carrier vehicle 4a enters the first port Pl, the article A placed on the first carrier vehicle 4a is received into the lifting base 16. By lowering the lifting table 28c of the first carrier vehicle 4a in this state, the article A is transferred onto the lifting base 16 from the first carrier vehicle 4a. When the article A is transferred to the lifting base 16, the sway suppression mechanism 24 of the lifting base 16 retracts the respective arms 24d, and moves the restrictors to the non-abutment position.

Furthermore, the lifting device 20 of the inter-floor transport device 2 raises the lifting base 16, and moves the lifting base 16 to the third port P3 of the second floor F2, by winding up the belts 18. When the lifting base 16 moves to the third port P3, the sway suppression mechanism 24 unwinds the respective arms 24d again, and moves the restrictors to the abutment position to reduce or prevent lateral sway of the lifting base 16. Then, the second carrier vehicle 6b of the second floor F2 travels, and moves to below the lifting base 16 stopping in the third port P3. By raising the lifting table 28c of the second carrier vehicle 6b in this state, the article A placed on the lifting base 16 is supported by the lifting table 28c of the second carrier vehicle 6b, and the article A is transferred to the second carrier vehicle 6b from the lifting base 16.

Next, the second carrier vehicle 6b travels to the fourth port P4 of the second floor F2. Furthermore, the ceiling travel vehicle 8b of the second floor F2 travels to the position adjacent to the fourth port P4, extends the slide mechanism 34b from that position, and lifts the article A placed on the second carrier vehicle 6b. After contracting the slide mechanism 34b, the ceiling travel vehicle 8b transports the article A within the second floor F2.

On the other hand, when transporting the article A from the second floor F2 to the first floor F1, the article A transported by the ceiling travel vehicle 8b is placed on the first carrier vehicle 4b stopping in the second port P2 of the second floor F2. The first carrier vehicle 4b on which the article A is placed travels to the first port P1 of the second floor F2, where the article A is transferred onto the lifting base 16 of the inter-floor transport device 2.

Furthermore, the lifting device 20 of the inter-floor transport device 2 lowers the lifting base 16 by unwinding the belts 18, and moves the lifting base 16 to the third port P3 of the first floor F1. Subsequently, in the third port P3, the article A placed on the lifting base 16 is transferred to the second carrier vehicle 6a. Then, the second carrier vehicle 6a travels to the fourth port P4 of the first floor F1. Furthermore, the ceiling travel vehicle 8b of the first floor F1 travels to the position adjacent to the fourth port P4, lifts the article A placed on the second carrier vehicle 6a from that position, and transports the article A within the first floor F1.

Note that in the present example embodiment, in both the first and second floors, the article A is transferred onto the lifting base 16 from the first carrier vehicle in the first port P1, and the article A is transferred onto the second carrier vehicle from the lifting base 16 in the third port P3, but it is possible to arbitrarily set the port in which loading and unloading of the article A are performed. Further, both of loading of the article A onto the lifting base 16, and reception of the article A from the lifting base 16 may be performed in the same port.

According to the inter-floor transport device 2 of the example embodiment of the present invention, since the lifting base 16 is suspended by the belts 18 that are the suspenders, and the lifting base 16 is raised or lowered through the opening 10a formed in the floor surface 10 of the floor, by the lifting device 20, it is not necessary to lay a structure such as a guide rail through the opening 10a formed in the floor surface 10, and it is possible to transport the article A between the plurality of floors with the simple structure. Further, since a rail or the like that extends through the opening 10a formed in the floor surface 10 is not required, it is possible to reduce the size of the opening 10a, and it is possible to install the inter-floor transport device 2 in the small floor area.

Further, according to the inter-floor transport device 2 of the present example embodiment, since the restrictor (the arm 24d and the guide rollers 24f) is moved between the abutment position (FIG. 8) where it abuts on the plate materials 22b that is the abutment to restrict movement in the lateral direction of the lifting base 16 and the non-abutment position (FIG. 6), it is possible to reduce or prevent sway of the lifting base 16 when movement in the lateral direction of the lifting base 16 is desired to be reduced or prevented at a time of loading and unloading of the article A to and from the lifting base 16, and the like.

Furthermore, according to the inter-floor transport device 2 of the present example embodiment, since the fire door 13 (FIG. 1) that closes the opening 10a to allow the first floor F1 and the second floor F2 to communicate with each other is included, it is possible to prevent a fire from spreading through the opening 10a during a fire.

Further, according to the inter-floor transport system 1 of an example embodiment of the present invention, since the first carrier vehicles 4a and 4b that each move the article A transported by the inter-floor transport device 2 within the one floor are included, it is possible to easily transport the article A transported by the inter-floor transport device 2 within the floor of the transport destination.

Furthermore, according to the inter-floor transport system 1 of the present example embodiment, since the transfer devices 28a of the first carrier vehicles 4a and 4b each include the lifting table 28c, and it is possible to support the article A on the lifting table 28c by raising the lifting table 28c through the cutout 16d (FIG. 10) of the lifting base 16, it is possible to transfer the article A to and from the lifting base 16 by the lifting table 28c capable of only a simple up-and-down movement.

Further, according to the inter-floor transport system 1 of the present example embodiment, since the first carrier vehicles 4a and 4b, and the second carrier vehicles 6a and 6b that move on the second rail 26b laid more upward than the first carrier vehicles 4a and 4b are included, it is possible to transfer the article A at the two spots (the first port Pl and the third port P3) within the one floor, from the lifting base 16 capable of only moving in the up-down direction, and it is possible to improve transport efficiency of the article A by the inter-floor transport system 1.

Furthermore, according to the inter-floor transport system 1 of the present example embodiment, since the ceiling travel vehicles 8a and 8b that receive the article A moved by the first carrier vehicles 4a and 4b and the second carrier vehicles 6a and 6b are included, it is possible to transport the article efficiently within the floors. Further, since the ceiling travel vehicles 8a and 8b can receive the article A moved by the first carrier vehicles 4a and 4b and the second carrier vehicles 6a and 6b in the same reception position (vertically above the second port P2), it is possible to transfer the article A to the ceiling travel vehicles 8a and 8b from the respective carrier vehicles in the small space.

While example embodiments of the present invention have been described above, it is to be understood that variations and modifications will be apparent to those skilled in the art without departing from the scope and spirit of the present invention. The scope of the present invention, therefore, is to be determined solely by the following claims.

1-7. (canceled)

8: An inter-floor transport device that transports an article between a plurality of floors separated in an up-down direction, the inter-floor transport device comprising:
a lifting base to support the article to be transported;
a plurality of suspenders to suspend the lifting base; and
a lifting device that is installed above the lifting base to raise the lifting base from a floor on a lower side to a floor on an upper side or lower the lifting base from the floor on the upper side to the floor on the lower side through an opening in a floor surface of the floor by winding up or unwinding the suspenders.

9: The inter-floor transport device according to claim 8, further comprising an abutment that is provided to be adjacent to a track where the lifting base rises and lowers, wherein the lifting base includes a restrictor to restrict movement in a lateral direction of the lifting base, and the restrictor is movable between an abutment position at which the restrictor abuts on the abutment to restrict movement in the lateral direction of the lifting base, and a non-abutment position that is spaced away from the abutment.

10: The inter-floor transport device according to claim 8, further comprising a fire door configured to close the opening between the two floors.

11: An inter-floor transport system that transports an article between a plurality of floors overlapping in an up-down direction, the inter-floor transport system comprising:
the inter-floor transport device according to claim 8; and
a first carrier vehicle to move the article transported by the inter-floor transport device within one floor; wherein
the first carrier vehicle includes a transfer device to receive the article from the lifting base of the inter-floor transport device, and a traveling device for the first carrier vehicle to move within a floor in which the first carrier vehicle is installed.

12: The inter-floor transport system according to claim 11, wherein the transfer device of the first carrier vehicle includes a lifting table to place the article transported by the inter-floor transport device thereon, and when receiving the article from the lifting base of the inter-floor transport device, the first carrier vehicle moves to below the lifting base, thereafter, raises the lifting table through a cutout in the lifting base, and supports the article placed on the lifting base, on the lifting table.

13: The inter-floor transport system according to claim 11, further comprising:
a second carrier vehicle to move above the first carrier vehicle, within a same floor as the first carrier vehicle, the second carrier vehicle being movable on a pair of rails that are laid above the first carrier vehicle; wherein
when the second carrier vehicle receives an article from the inter-floor transport device, the second carrier vehicle moves to below the lifting base of the inter-floor transport device along the pair of rails;
when the first carrier vehicle receives an article from the inter-floor transport device, the second carrier vehicle retracts from the track of the lifting base of the inter-floor transport device, and the inter-floor transport device lowers the lifting base through between the pair of rails to transfer the article to the first carrier vehicle that is moved to below the lifting base.

14: The inter-floor transport system according to claim 13, further comprising:
a ceiling travel vehicle installed on a same floor as the first carrier vehicle and the second carrier vehicle, the ceiling travel vehicle being configured to move to a predetermined reception position and receive articles moved by the first carrier vehicle and the second carrier vehicle; wherein
when receiving the article from the first carrier vehicle, the ceiling travel vehicle moves to the reception position, and receives the article moved by the first carrier vehicle from above; and
when receiving the article from the second carrier vehicle, the ceiling travel vehicle moves to the reception position, and receives the article moved by the second carrier vehicle from a side.
